(19) United States
(12) Patent Application Publication
(10) Pub. No.: US 2006/0063688 A1
(43) Pub. Date: Mar. 23, 2006

(54) Photoresist stripping solution and method of treating substrate with the same

(76) Inventors: Shigeru Yokoi, Kawasaki-shi (JP); Takayuki Haraguchi, Kawasaki-shi (JP); Kazumasa Wakiya, Kawasaki-shi (JP); Akira Kumazawa, Kawasaki-shi (JP)

Correspondence Address: WENDEROTH, LIND & PONACK, L.L.P., 2033 K STREET N. W., SUITE 800, WASHINGTON, DC, 20006-1021, US

(21) Appl. No.: 11/228,278

(22) Filed: Sep. 19, 2005

(30) Foreign Application Priority Data
Sep. 17, 2004 (JP) 2004-271945

(51) Int. Cl. G03F 7/42

(52) U.S. Cl. 510/176

(57) ABSTRACT

Disclosed is a photoresist stripping solution comprising: (a) a salt of hydrofluoric acid with a base free from metallic ions; and (b) a water-soluble organic solvent, wherein the content of the component (a) is 0.001 to 0.1 mass % based on the total mass of the photoresist stripping solution. Also disclosed is a method of treating a substrate, which comprises: forming a photoresist film on a substrate; subjecting it to light exposure and then to development; etching thereof with a photoresist pattern as a mask pattern; ashing the mask; and bringing the photoresist stripping solution into contact with the substrate.

### BACKGROUND OF THE INVENTION

1. Field of the Invention

The present invention relates to a photoresist stripping solution and a method of treating a substrate with the same. More specifically, the present invention relates to a photoresist stripping solution which is excellent in corrosion prevention of metallic wiring of Cu or the like, is excellent in strippability of a photoresist film or etching or ashing residues, and can suppress damages to a film of low dielectric constant (hereinafter, “low-k”) particularly using a material of low dielectric constant, as well as a method of treating a substrate with the same. The photoresist stripping solution according to the present invention is advantageously applied to production of semiconductor elements, such as IC and LSI, and liquid crystal panels.

2. Description of the Related Art

Semiconductor elements, such as IC and LSI, and liquid crystal panels are produced by applying a photoresist uniformly onto an electroconductive metallic film or an insulating film such as SiO₂ film formed on a substrate such as a silicon wafer, forming a photoresist pattern by selective light exposure and subsequent development thereof, then etching the electroconductive metallic film or the insulating film selectively through the pattern as a mask to form a fine circuit, followed by ashing thereof, and removing an unnecessary photoresist layer with a photoresist stripping solution (hereinafter, also referred to simply as “stripping solution).

Materials used for forming the electroconductive metallic layer include, for example, aluminum (Al), aluminum alloys (Al alloys) such as aluminum-silicon (Al—Si), aluminum-copper (Al—Cu), and aluminum-silicon-copper (Al—Si—Cu), titanium (Ti), and titanium alloys (Ti alloys) such as titanium nitride (TiN) and titanium tungsten (TiW), as well as tantalum (Ta), tantalum nitride (TaN), tungsten (W), tungsten nitride (WN), copper (Cu) or the like are used. A single layer or a plurality of layers of these electroconductive metal materials is formed on a substrate.

The insulating film that can be used include, for example, an SiO₂ film made of a chemical vapor deposition (CVD) material, such as silicon oxide (SiO₂) or silicon nitride (Si₃N₄), an inorganic spin-on-glass (SOG) film made of an inorganic coating material, such as hydrogen silsesquioxane (HSQ), and an organic SOG film made of methyl silsesquioxane (MSQ). To meet demands for large-scale integration circuits (ultra LSI or ULSI) with higher speed and lower electricity consumption in the future, development of a low-k film capable of improving electric properties of wiring by combination with a Cu wiring material is advancing. For lower dielectric constant, development of a porous film as the low-k film is desired.

As integrated circuits become increasingly dense in recent years, dry etching capable of fine etching at higher density is mainly applied. Also, plasma ashing is conducted to remove an unnecessary photoresist layer after etching. Even after the etching and ashing treatments, denatured film residues may remain as a horn-shaped side wall or residues derived from another component may remain adhering to a pattern side or on the bottom. When a pattern is formed on a substrate having an Si-based interlaminar insulating film or low-k film, Si-based residues can be formed. When a metallic film at the time of etching is scraped off, a metallic deposition is generated. Thus, various residues are generated, and unless these are completely removed, there arise problems such as a reduction of yield in production of semiconductors.

Particularly in higher integration and higher density in a substrate in recent years, etching and ashing conditions become increasingly harder, and demands for corrosion prevention of metallic wiring, strippability of residues or the like, are significantly higher than ever before.

Under these circumstances, the development of a photoresist stripping solution capable of meeting the requirements described above has advanced in recent years for the purpose of preventing the corrosion of metallic wiring in devices having Al-based wiring made of Al or an Al alloy, or devices having Cu-based wiring.

For example, the following patent documents disclose such photoresist stripping solutions or related techniques: Japanese Patent Application Laid-open No. 2001-242642 discloses a treatment solution (stripping solution) including a salt of hydrofluoric acid with a base free from metallic ions and incorporating at least a polyhydric alcohol and a water-soluble organic solvent; Japanese Patent Application Laid-open No. 2003-114539 discloses a photoresist stripping solution including (a) a salt of hydrofluoric acid with a base free from metallic ions, (b) a water-soluble organic solvent, (c) a mercapto group-containing corrosion preventive, and (d) water; Japanese Patent Application Laid-open No. 2003-174002 discloses a resist stripping solution composition including 0.001 to 0.5 wt % of a fluorine compound and 1 to 99 wt % of an ether solvent, the balance being water; and Japanese Patent Application Laid-open No. 2001-100436 discloses a semiconductor device detergent which is an aqueous solution including (a) 0.01 to 3 wt % of fluorine component and (b) 3 to 30 wt % of a polyol.

Japanese Patent Application Laid-open No. 2001-242642 relates to a treatment solution capable of preventing corrosion of metallic wiring and removing residues reliably, which is not directed to a Cu/low-k substrate; damages to a low-k film by the treatment solution are not taken into consideration. That is, although it is described therein that the content of the salt of hydrofluoric acid with the base free from metallic ions is preferably 0.01 to 10 wt %, this description relates to an aluminum circuit board (including Al—Si, Al—Si—Cu).

Japanese Patent Application Laid-open No. 2003-114539 relates to the photoresist stripping solution excellent in preventing the corrosion of metallic wiring of both Al and Cu and excellent in strippability of a photoresist film and residues after ashing, and describes that the content of the salt (fluorinated compound) of hydrofluoric acid with the base free from metallic ions is 0.1 to 10 wt %. Given this amount of the salt added, however, damages to the recent low-k film that is made significantly porous are concerned.

It is described in Japanese Patent Application Laid-open Nos. 2003-174002 and 2001-100436, that the content of the fluorine compound is 0.001 to 0.5 wt %. However, these patent documents relate to an Al circuit board (including Al—Si, Al—Si—Cu), while it is not directed to a Cu/low-k substrate. In addition, the object of these patent documents is to prevent corrosion of metallic wiring upon rinsing, and damages to the low-k film are not taken into consideration.

As described above, the conventional photoresist stripping solutions are intended to improve both strippability and prevention of metal corrosion, and these photoresist stripping solutions are not directed to the Cu/low-k substrate, which is considered to be more important in the future. Also, these photoresist stripping solutions do not take prevention of damages particularly to the low-k film into consideration, and are poor in the effect.

### SUMMARY OF THE INVENTION

The present invention has been achieved in light of the circumstances described above. It is an object of the present invention to provide a photoresist stripping solution that does not generate corrosion in metallic wiring including Cu wiring in the Cu/low-k substrate, which meets demands for higher speed and lower electricity consumption for ultra-LSI in photolithography used in formation of recent fine and multilayer semiconductors and liquid crystal displays, that does not give damages even to the low-k film, that is excellent in strippability of a photoresist film and a residual film after ashing, without giving damages to a porous insulating film consisting of the low-k film, and that is excellent in strippability of a photoresist film and a residual film after ashing. Also, it is another object of the present invention to provide a method of treating a substrate with the above-mentioned photoresist stripping solution.

To achieve the above-mentioned object, the inventors of the present inventors have made extensive studies on the composition of a photoresist stripping solution and the content of each component. As a result, they have found that a photoresist stripping solution containing a salt of hydrofluoric acid with a base free from metallic ions in a specific content and a water-soluble organic solvent has properties of generating no corrosion in metallic wiring including Cu wiring, giving no damage even to a low-k film on the Cu/low-k substrate, and being excellent in strippability of a photoresist film and a residual film after ashing. They have achieved the present invention based on this finding.

According to an aspect, the present invention provides a photoresist stripping solution comprising: (a) a salt of hydrofluoric acid with a base free from metallic ions; and (b) a water-soluble organic solvent, wherein the content of the component (a) is 0.001 to 0.1 mass % based on the total mass of the photoresist stripping solution.

The content of the component (a) is preferably 0.001 to 0.6 mass % based on the total mass of the photoresist stripping solution. The water-soluble organic solvent is preferably γ-butyrolactone, propylene glycol or a mixture of these.

The photoresist stripping solution of the present invention may further include (c) water and (d) a corrosion preventive.

The corrosion preventive is preferably at least one member selected from the group consisting of a mercapto group-containing compound and a benzotriazole compound.

The mercapto group-containing compound preferably is a compound having at least one of a hydroxyl group and a carboxyl group at at least one of the α-position and β-position relative to a mercapto group-bound carbon atom. Preferably, the mercapto group-containing compound is at least one member selected from the group consisting of 1-thioglycerol, 2-mercaptoethanol, 3-(2-aminophenylthio)-2-hydroxypropyl mercaptan, 3-(2-hydroxyethylthio)-2-hydroxypropyl mercaptan, 2-mercaptopropionic acid, and 3-mercaptopropionic acid.

Preferably, the benzotriazole compound is at least one member selected from the group consisting of 1-(2,3-dihydroxypropyl)benzotriazole, 2,2′-{[(4-methyl-1H-benzotriazol-1-yl)methyl]imino}bisethanol, and 2,2′-{[(5-methyl-1H-benzotriazol-1-yl)methyl]imino}bisethanol.

In the photoresist stripping solution of the present invention, the content of the component (b) is preferably 20 to 90 mass %, the content of the component (c) is preferably 10 to 80 mass %, and the content of the component (d) is preferably 0.01 to 10 mass % based on the total mass of the photoresist stripping solution.

The component (a) in the photoresist stripping solution is preferably ammonium fluoride. In this case, the photoresist stripping solution may further include (e) a salt of hydrofluoric acid with at least one of a quaternary ammonium hydroxide and an alkanolamine. The quaternary ammonium hydroxide is represented by formula (1): 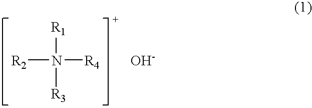
wherein R¹, R², R³, and R⁴ independently represent a C₁ to C₄ alkyl or a C₁ to C₄ hydroxyalkyl group.

The mass ratio of the component (a) to the component (e) incorporated is 2:8 to 8:2.

The photoresist stripping solution of the present invention is suitable for use in washing substrates with an insulating film made of a low-k material having a dielectric constant equal to or less than 2.7.

According to another aspect, the present invention provides a method of treating a substrate, which comprises: forming a photoresist film on a substrate; subjecting it to light exposure and then to development; etching thereof with a photoresist pattern as a mask pattern; ashing the mask; and bringing the above-mentioned photoresist stripping solution into contact with the substrate.

The other objects, features, and advantages of the present invention are specifically set forth in or will become apparent from the following detailed description of the invention when read in conjunction with the accompanying drawings.

### BRIEF DESCRIPTION OF THE DRAWING

FIG. 1 is a graph showing effects of a photoresist stripping solution according an embodiment of the present invention on inhibition of damage to a borophosphosilicate glass (BPSG) film.

### DETAILED DESCRIPTION

Exemplary embodiments of the present invention are described below. The present invention is not limited thereto.

The photoresist stripping solution of the present invention includes (a) a salt of hydrofluoric acid with a base free from metallic ions and (b) a water-soluble organic solvent, wherein the content of the component (a) is 0.001 to 0.1 mass % based on the total mass of the stripping solution. The photoresist stripping solution according to the invention includes the salt of hydrochloric acid with the base free from metallic ions in a content of 0.001 to 0.1 mass % based on the total mass of the stripping solution, so that it is usable for a low-k film, particularly a low-k film made significantly porous, in a Cu/low-k substrate, is excellent in strippability of a photoresist and residues after ashing, and can reduce damages thereto.

Contents of the component (a) higher than 0.1 mass % are not preferable, because damages to a low-k film become significant. Contents of the component (a) lower than 0.001 mass % are not preferable either, because the photoresist stripping solution is poor in an ability to remove residues at the time of etching.

From the viewpoint of further suppressing damages to a low-electric film, the content of the component (a) is preferably equal to or less than 0.06 mass %.

The component (a) is a salt of hydrofluoric acid with a base free from metallic ions. Examples of the base free from metallic ions that can be used advantageously in the invention include organic amines such as a hydroxylamine, a primary, secondary, or tertiary aliphatic amine, an alicyclic amine, an aromatic amine, or a heterocyclic amine, ammonia water, and a lower alkyl quaternary ammonium hydroxide.

Specific examples of the hydroxylamine include hydroxylamine (NH₂OH), N-methylhydroxylamine, N,N-dimethylhydroxylamine, and N,N-diethylhydroxylamine.

Specific examples of the primary aliphatic amine include monoethanolamine, ethylenediamine, and 2-(2-aminoethylamino)ethanol.

Specific examples of the secondary aliphatic amine include diethanolamine, N-methylaminoethanol, dipropylamine, and 2-ethylaminoethanol.

Specific examples of the tertiary aliphatic amine include dimethylaminoethanol and ethyldiethanolamine.

Specific examples of the alicyclic amine include cyclohexylamine and dicyclohexylamine.

Specific examples of the aromatic amine include benzylamine, dibenzylamine, and N-methylbenzylamine.

Specific examples of the heterocyclic amine include pyrrole, pyrrolidine, pyrrolidone, pyridine, morpholine, pyrazine, piperidine, N-hydroxyethyl piperidine, oxazole, and thiazole.

Specific examples of the lower alkyl quaternary ammonium hydroxide include tetramethylammonium hydroxide, tetraethylammonium hydroxide, tetrapropylammonium hydroxide, trimethylethylammonium hydroxide, (2-hydroxyethyl)-trimethylammonium hydroxide, (2-hydroxyethyl)triethyl-ammonium hydroxide, (2-hydroxyethyl)tripropylammonium hydroxide, and (1-hydroxypropyl)trimethylammonium hydroxide.

Among these bases, ammonia water, monoethanolamine, N-methylaminoethanol, tetramethylammonium hydroxide, and (2-hydroxyethyl)trimethylammonium hydroxide are preferably used from the viewpoint of availability and excellent safety.

The bases free from metallic ions may be used alone or as a mixture of two or more thereof.

As the component (a), the salt with the base free from metallic ions and hydrofluoric acid can be produced by adding a base free from metallic ions to 50 to 60% commercial hydrofluoric acid. As the salt, ammonium fluoride (NH₄F) is used most preferably.

In the photoresist stripping solution of the invention, the component (b) is a water-soluble organic solvent, and conventionally used organic solvents can be used as the component (b). The water-soluble organic solvent may be an organic solvent that is compatible with water or another component to be incorporated. Specific examples of the water-soluble organic solvent include:

sulfoxides such as dimethyl sulfoxide;

sulfones such as dimethyl sulfone, diethyl sulfone, bis(2-hydroxyethyl) sulfone, and tetramethylene sulfone;

amides such as N,N-dimethylformamide, N-methyl-formamide, N,N-dimethylacetamide, N-methylacetamide, and N,N-diethylacetamide;

lactams such as N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone;

imidazolidinones such as 1,3-dimethyl-2-imidazolidinone, 1,3-diethyl-2-imidazolidinone, and 1,3-diisoproyl-2-imidazolidinone;

lactones such as γ-butyrolactone, β-propiolactone, β-valerolactone, δ-valerolactone, γ-caprolactone, and ε-caprolactone;

polyhydric alcohols such as ethylene glycol, propylene glycol, butylene glycol, pentylene glycol, hexylene glycol, and glycerin; and

polyhydric alcohol derivatives such as ethylene glycol monomethyl ether, ethylene glycol monoethyl ether, ethylene glycol monobutyl ether, ethylene glycol monomethyl ether acetate, ethylene glycol monoethyl ether acetate, diethylene glycol monomethyl ether, diethylene glycol monoethyl ether, diethylene glycol monobutyl ether, propylene glycol monomethyl ether, propylene glycol monoethyl ether, propylene glycol monopropyl ether, and propylene glycol monobutyl ether.

Among these water-soluble organic solvents, lactones and polyhydric alcohols are preferable from the viewpoint of damage reduction to a low-k film, and among these solvents, y-butyrolactone and propylene glycol are more preferable. One or more kinds of the component (b) can be used.

From the viewpoint of the balance among the removability of residues, corrosion of metallic wiring during washing treatment, and damages to a low-k film, the content of the component (b) is preferably 20 to 90 mass %, and more preferably 30 to 80 mass %, based on the total mass of the stripping solution of the invention. When the content of the component (b) is too high, i.e., more than 90 mass %, stripping performance is likely to be lowered, while when the content is too low, i.e., less than 20 mass % based on the total mass of the stripping solution, the corrosion of various kinds of metals and damages to a low-k film are likely to be generated.

The photoresist stripping solution of the invention includes (c) water and (d) a corrosion preventive in addition to the components (a) and (b) described above.

The amount of water incorporated as the component (c) is the balance excluding the other components contained in the photoresist stripping solution of the invention.

As the corrosion preventive, the component (d) is not particularly limited insofar as it can prevent corrosion of metal atoms such as in Cu wiring used in wiring. As the corrosion preventive, any conventionally used corrosion preventive can be used. Such corrosion preventives include, for example, aromatic hydroxy compounds, benzotriazole compounds, sugar alcohol compounds, and mercapto group-containing compounds. Among these compounds, the mercapto group-containing compounds and benzotriazole compounds are preferable from the viewpoint of preventing corrosion of various kinds of metals.

The mercapto group-containing compound is preferably a compound having at least one of a hydroxyl group and a carboxyl group at at least one of the α-position and β-position relative to a mercapto group-bound carbon atom. Preferable examples of such compounds include 1-thio-glycerol, 2-mercaptoethanol, 3-(2-aminophenylthio)-2-hydroxypropyl mercaptan, 3-(2-hydroxyethylthio)-2-hydroxypropyl mercaptan, 2-mercaptopropionic acid, and 3-mercapto-propionic acid. Among these compounds, 1-thioglycerol can be particularly preferably used. By using such corrosion preventive, the photoresist stripping solution of the invention can have an effect of not only being excellent in corrosion prevention of metallic wiring such as Cu wiring but also preventing precipitation of the corrosion preventive.

One or more kinds of the component (d) can be used. The ratio of the component (d) incorporated is preferably 0.01 to 10 mass %, more preferably 0.01 to 5 mass %, based on the total mass of the photoresist stripping solution of the invention. When the ratio of the component (d) incorporated is too low, i.e., less than 0.01 mass %, there is the fear that corrosion particularly of Cu wiring can not be effectively prevented.

The benzotriazole compounds include those compounds represented by the following formula (2): 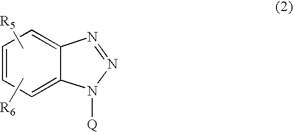
wherein Q represents a hydrogen atom, a hydroxyl group, a substituted or unsubstituted C₁ to C₁₀ hydrocarbon group (provided that the hydrocarbon group may have an amide linkage or an ester linkage in its structure), an aryl group, or a group represented by the following formula (3):

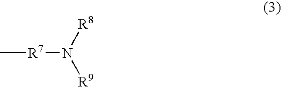

In the formula (3), R⁷ represents a C₁ to C₆ alkyl group; R⁸ and R⁹ independently represent a hydrogen atom, a hydroxyl group, or a C₁ to C₆ hydroxyalkyl group or alkoxyalkyl group. In the formula (2), R⁵ and R⁶ independently represent a hydrogen atom, a substituted or unsubstituted C₁ to C₁₀ hydrocarbon group, a carboxyl group, an amino group, a hydroxyl group, a cyano group, a formyl group, a sulfonylalkyl group, or a sulfone group.

The “hydrocarbon group” mentioned above is an organic group consisting of carbon atoms and hydrogen atoms. In the invention, the hydrocarbon group in the definition of Q, R⁵ , and R⁶ may be an aromatic hydrocarbon group or an aliphatic hydrocarbon group, may have a saturated or unsubstituted bond, and may be a linear or branched chain. Examples of the substituted hydrocarbon group include, for example, a hydroxyalkyl group, and an alkoxyalkyl group.

In the case of a substrate having pure Cu wiring formed thereon, Q in the formula (2) is particularly preferably a group represented by the formula (3). It is particularly preferable that in the formula (3), R⁸ and R⁹ independently represent a C₁ to C₆ hydroxyalkyl group or alkoxyalkyl group. When at least one of R⁸ and R⁹ is a C₁ to C₆ alkyl group, the physical properties of the benzotriazole compound of such formulation are poor in water solubility, but when another component dissolving the compound is present in the treatment solution, the compound in which at least one of R⁸ and R⁹ is a C₁ to C₆ alkyl group can be preferably used.

In the formula (2), Q is preferably a water-soluble group. Specifically, Q is preferably a hydrogen atom, a C₁ to C₃ alkyl group (that is, a methyl group, an ethyl group, a propyl group, or an isopropyl group), a C₁ to C₃ hydroxy alkyl group, or a hydroxyl group, from the viewpoint of corrosion prevention of an inorganic material layer.

Specific examples of the benzotriazole compound include, for example, benzotriazole, 5,6-dimethylbenzotriazole, 1-hydroxybenzotriazole, 1-methyl-benzotriazole, 1-aminobenzotriazole, 1-phenylbenzotriazole, 1-hydroxy-methylbenzotriazole, methyl 1-benzotriazole-carboxylate, 5-benzotriazolecarboxylic acid, 1-methoxy-benzotriazole, 1-(2,2-dihydroxyethyl)benzotriazole, 1-(2,3-dihydroxypropyl)-benzotriazole, as well as benzotriazole compounds commercially available as “Irgamet” series from Ciba Specialty Chemicals, such as 2,2′-{[(4-methyl-1H-benzo-triazol-1-yl)methyl]imino}bisethanol, 2,2′-{[(5-methyl-1H-benzotriazol-1-yl)methyl]imino}bisethanol, 2,2′-{[(4-methyl-1H-benzotriazol-1-yl)methyl]imino}bisethane, and 2,2′-{[(4-methyl-1H-benzotriazol-1-yl)methyl]imino}-bispropane. Among these compounds, 1-(2,3-dihydroxy-propyl)benzotriazole, 2,2′-{[(4-methyl-1H-benzotriazol-1-yl)methyl]imino}bisethanol, and 2,2′-{[(5-methyl-1H-benzo-triazol-1-yl)methyl]imino}bisethanol are preferably used. The benzotriazole compounds can be used alone or as a mixture of two or more thereof.

The component (a) in the photoresist stripping solution of the invention is preferably ammonium fluoride. When ammonium fluoride is used, the photoresist stripping solution preferably contains (e) a salt of hydrofluoric acid and a quaternary ammonium hydroxide represented by formula (1) and/or an alkanolamine. 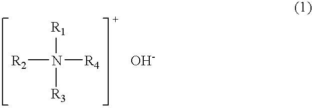
wherein R¹, R², R³, and R⁴ independently represent a C₁ to C₄ alkyl or a C₁ to C₄ hydroxyalkyl group. By further incorporating the component (e), the strippability of the stripping solution can further be improved while damages to Cu are suppressed at a low level.

Specific examples of the quaternary ammonium hydroxide represented by the formula (1) include tetramethylammonium hydroxide (TMAH), tetraethylammonium hydroxide, tetrapropylammonium hydroxide, tetrabutylammonium hydroxide, monomethyltripropylammonium hydroxide, trimethylethylammonium hydroxide, (2-hydroxyethyl)trimethylammonium hydroxide, (2-hydroxyethyl)triethylammonium hydroxide, (2-hydroxyethyl)tripropyl ammonium hydroxide, and (1-hydroxy-propyl)trimethyl ammonium hydroxide. Among these compounds, TMAH, tetraethylammonium hydroxide, tetrapropylammonium hydroxide, tetrabutylammonium hydroxide, monomethyl-tripropylammonium hydroxide, and (2-hydroxyethyl)trimethyl-ammonium hydroxide are preferable from the viewpoint of availability and excellent safety.

The alkanolamine includes monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethyl-ethanolamine, N-butylethanolamine, N-methyldiethanolamine, monoisopropanolamine, diisopropanolamine, and triisopropanolamine. Among these compounds, N-methyl-ethanolamine is particularly preferable from the viewpoint of corrosion prevention of Cu wiring.

One or more kinds of the component (e) can be used. When the component (e) is incorporated, the amount of the component (e) incorporated is preferably 0.001 to 0.1 mass %, more preferably 0.001 to 0.06 mass %, based on the total mass of the photoresist stripping solution of the invention. When the amount of the component (e) incorporated is too high, i.e., more than 0.1 mass %, various kinds of metallic wiring are liable to corrosion.

When the component (e) is incorporated into the photoresist stripping solution of the invention, the ratio of ammonium fluoride incorporated as the component (a) to the component (e) (ammonium fluoride : the component (e)) is preferably 2:8 to 8:2 by mass, more preferably 3:7 to 7:3.

In respect of the improvement of permeability, an acetylene alcohol/alkylene oxide adduct obtained by adding an alkylene oxide to acetylene alcohol may be incorporated as an optionally added component to the photoresist stripping solution of the invention.

As the acetylene alcohol, the compound represented by the following formula (4) is preferably used.

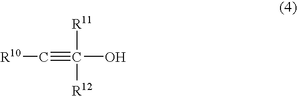

Among the compounds represented by the formula (4), those compounds in which R¹⁰ is a hydrogen atom, or a compound represented by the following formula (5) are preferably used.

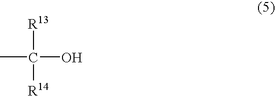

In the formulae (4) and (5), R¹¹, R¹², R¹³, and R¹⁴ independently represent a hydrogen atom or a C₁ to C₆ alkyl group.

As the acetylene alcohol, for example, “Surfynol” and “Olfin” (both manufactured by Air Product and Chemicals Inc.), are commercially available and preferably used. Among these products, “Surfynol 104”, “Surfynol 82”, or a mixture thereof, is used preferably in light of its physical properties. In addition, “Olfin B”, “Olfin P”, “Olfin Y” or the like can also be used.

As the alkylene oxide to be added to acetylene alcohol, it is preferable to use ethylene oxide, propylene oxide, or a mixture thereof.

In the photoresist stripping solution of the invention, a compound represented by the following formulae (6) or (7) is preferably used as the acetylene alcohol/alkylene oxide adduct.

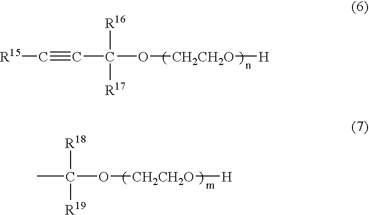

In the formula (6), R¹⁵ represents a hydrogen atom, or in the formulae (6) and (7), R¹⁶, R¹⁷, R¹⁸, and R¹⁹ independently represent a hydrogen atom or a C₁ to C₆ alkyl group. (n+m) represents an integer of 1 to 30, and depending on the number of ethylene oxide units added, properties such as solubility in water and surface tension are slightly changed.

The acetylene alcohol/alkylene oxide adduct is a substance known per se as a surfactant. As the adduct, “Surfynol” series (manufactured by Air Product and Chemicals Inc.) or “Acetylenol” series (manufactured by Kawaken Fine Chemicals Co., Ltd.) are commercially available and preferably used. “Surfynol 440” (n+m=3.5), “Surfynol 465” (n+m=10), “Surfynol 485” (n+m=30), “Acetylenol EL” (n+m=4), “Acetylenol EH” (n+m=10), or a mixture thereof, is used preferably in consideration of changes in properties such as solubility in water and surface tension, depending on the number of ethylene oxide units added. Among these products, a mixture of “Acetylenol EL” and “Acetylenol EH” is preferably used, and a mixture thereof in a ratio of from 2:8 to 4:6 (parts by mass) is particularly preferable.

By incorporating the acetylene alcohol/alkylene oxide adduct, the permeability and wetting properties of the stripping solution itself can be improved.

When the acetylene alcohol/alkylene oxide adduct is incorporated into the photoresist stripping solution of the invention, the amount of the incorporated adduct is preferably about 0.05 to 5 mass %, more preferably about 0.1 to 2 mass %. When the content is higher than the above range, bubbles may be generated, and the improvement of wetting properties may be saturated and can not be improved even by further adding the adduct, while when the content is lower than the range, desirably sufficient wetting properties are hardly obtained.

To effect stripping treatment in a short time, an acidic compound may be incorporated into the photoresist stripping solution of the invention. The acidic compounds include, for example, hydrofluoric acid, acetic acid, and glycolic acid. When the acidic compound is to be incorporated, the amount of the compound is preferably about 1 mass % or less. When the acidic compound is incorporated, the strippability of particularly an Si-based deposition is improved, and thus there is achieved an excellent effect of removing the Si-based deposition in addition to a reduction in time of stripping treatment.

The photoresist stripping solution of the invention can be used advantageously in photoresists including negative- and positive-type photoresists developable with an aqueous alkali solution. Such photoresists include, but is not limited to:

(i) positive-type photoresist containing a naphthoquinone diazide compound and novolak resin,

(ii) positive-type photoresist containing a compound generating an acid upon light exposure, a compound to be decomposed with an acid to increase solubility in an aqueous alkali solution, and an alkali-soluble resin,

(iii) positive-type photoresist containing a compound generating an acid upon light exposure and an alkali-soluble resin having a group to be decomposed with an acid to increase solubility in an aqueous alkali solution, and

(iv) negative-type photoresist containing a compound generating an acid by light, a crosslinking agent, and an alkali-soluble resin.

The method of treating a substrate according to the invention includes the steps of: forming a photoresist pattern obtained by photolithography; etching an electroconductive metallic film or a low-k film selectively through the photoresist pattern as a mask; subjecting the photoresist pattern to a plasma ashing treatment; and stripping a denatured film (photoresist residue), a metallic deposition or the like, after the plasma ashing.

The photoresist stripping solution of the invention has a unique effect of being excellent in strippability of residues (denatured photoresist film, metallic deposition or the like) after ashing, in stripping of a photoresist formed on a substrate having metallic wiring including Cu wiring, in prevention of corrosion of a metallic wiring substrate, and in prevention of damages to a low-k film in the Cu/low-k substrate.

The metallic wiring includes, but not limited to, copper (Cu), aluminum (Al), aluminum alloys such as aluminum-silicon (Al—Si) and aluminum-silicon-copper (Al—Si—Cu), titanium (Ti), and titanium alloys (Ti alloys) such as titanium nitride (TiN) and titanium tungsten (TiW).

Conventional stripping solutions are not directed to the Cu/low-k substrate and do not take prevention of damages particularly to the low-k film into consideration, while in the present invention, prevention of damages particularly to the low-k film can be improved by using the component (a) in an amount of 0.001 to 0.1 mass % based on the total mass of the stripping solution. Furthermore, strippability can further be improved while damages to Cu are suppressed at a low level by incorporating the component (e) in addition to the components (a) to (d), provided that ammonium fluoride is used as the component (a).

In the method of treating a substrate, a denatured photoresist film and a metallic deposition generated at the time of etching the metallic film adhere to, and remain as residues on, the surface of a substrate after plasma ashing. These residues are contacted with the photoresist stripping solution of the present invention to strip and remove the residues from the substrate. The plasma ashing is originally a method of removing a photoresist pattern, but the photoresist pattern often remains as a partially denatured film, and in this case, the present invention is particularly effective for complete removal of the denatured photoresist film.

Formation, light exposure, development, and etching of the photoresist layer are the conventional means, but not particularly limited thereto.

After the development step and stripping step, conventional rinsing with purified water, a lower alcohol, or the like, and drying may be conducted.

The stripping treatment is conducted usually by dipping, showering or the like. The stripping time may be a time enough to strip the residues, and is not particularly limited. It is usually about 1 to 20 minutes.

### EXAMPLES

The present invention is explained in more detail based on Examples below. Note that the invention is not limited by the Examples.

### Preparation Examples 1 to 5

As shown in Table 1 below, stripping solutions 1 to 5 as the photoresist stripping solutions of the present invention were prepared by mixing ammonium fluoride (NH₄F) as the component (a), 70 mass % of γ-butyrolactone as the component (b), 0.05 mass % of 1-thioglycerol and 0.09 mass % of 3-mercaptopropionic acid as the component (d), and 0.1 mass % of acetylenol as another component, the balance being water as the component (c). Ammonium fluoride as the component (a) was incorporated in amounts of 0.03, 0.04, 0.05, 0.06, and 0.07 mass % based on the total mass of the stripping solutions 1 to 5, respectively.

### Preparation Examples 6 to 10

As shown in Table 1 below, stripping solutions 6 to 10 as the photoresist stripping solutions of the invention were prepared by mixing ammonium fluoride (NH₄F) as the component (a), 50 mass % propylene glycol (PG) as the component (b), 0.05 mass % 1-thioglycerol as the component (d), and 0.1 mass % acetylenol as another component, the balance being water as the component (c). Ammonium fluoride as the component (a) was incorporated in amounts of 0.03, 0.04, 0.05, 0.06, and 0.07 mass % in the stripping solutions 6 to 10, respectively.

### Preparation Example 11

As a comparative stripping solution, stripping solution 11 was prepared by mixing 0.05 mass % ammonium fluoride (NH₄F) as the component (a), 95 mass % γ-butyrolactone as the component (b), 0.05 mass % 1-thioglycerol as the component (d), and 0.1 mass % acetylenol as another component, the balance being water as the component (c), as shown in Table 1 below.

### Preparation Example 12

As a comparative stripping solution, stripping solution 12 was prepared by mixing 0.15 mass % ammonium fluoride (NH₄F) as the component (a), 85 mass % γ-butyrolactone as the component (b), 0.05 mass % 1-thioglycerol as the component (d), and 0.1 mass % acetylenol as another component, the balance being water as the component (c), as shown in Table 1 below.

### Example 1 to 10 and Comparative Examples 1 to 2

Examination of Prevention of Damages to Low-k Material

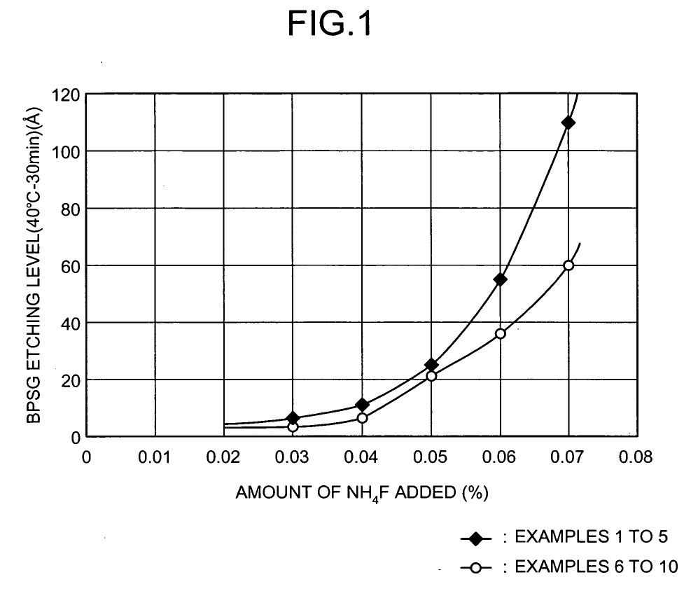

A substrate having borophosphosilicate glass (BPSG) applied as a film thereon was measured for film thickness by a Nanospec film thickness measuring apparatus and then treated by dipping for 30 minutes in the photoresist stripping solution stabilized at 40° C. in a thermostatic bath. After a dipping treatment, the substrate was rinsed with purified water and then measured again for film thickness by Nanospec, and the difference (angstrom, Å) in film thickness before and after the treatment was confirmed as an indicator of a BPSG etching level. As the photoresist stripping solution, each of the stripping solutions 1 to 12 prepared in the Preparation Examples were used. Table 2 shows the results of the difference (angstrom, Å) in film thickness as the BPSG etching level (angstrom, Å). A created graph wherein the amounts of ammonium fluoride (NH₄F) (mass %) incorporated as the component (a) are plotted on the abscissa and the BPSG etching levels (angstrom, Å) on the ordinate is shown in FIG. 1.

### Example 11 to 20 and Comparative Examples 3 to 4

A substrate having a Cu layer formed on a silicon wafer and an SiO₂ layer formed thereon by plasma CVD was coated with a positive-type photoresist TDUR-P015PM (manufactured by Tokyo Ohka Kogyo Co., Ltd.) by a spinner and then pre-baked at 80° C. for 90 seconds to form a photoresist layer of 0.7 μm in thickness thereon.

This photoresist layer was exposed to light via a mask pattern by using FPA3000EX3 (manufactured by Canon Inc.), then post-baked at 110° C. for 90 seconds, and developed with 2.38 mass % aqueous tetramethylammonium hydroxide (TMAH) solution, to form a hole pattern of 200 nm in diameter. Subsequently, the substrate was subjected to dry etching and then to plasma ashing.

Each treated substrate was dipped in each of the stripping solutions 1 to 12 at 25° C. for 5 minutes as shown in Table 1, and then subjected to a stripping treatment in each of Examples 11 to 20 and Comparative Examples 3 and 4. Strippability of residues after ashing was evaluated by observation under SEM (scanning electron microscope). The results are shown in Table 2.

TABLE 1
COMPOSITIONS OF PHOTORESIST STRIPPING SOLUTIONS

| | PREPARATION EXAMPLES | | PREPARATION EXAMPLES | |
|---|---|---|---|---|
| COMPOSITION | 1 TO 5 | | 6 TO 10 | |
| OF STRIPPING | STRIPPING | | STRIPPING | |
| SOLUTION | SOLUTIONS 1 TO 5 | wt % | SOLUTIONS 6 TO 10 | wt % |
| COMPONENT | NH₄F | PREDETERMINED | NH₄F | PREDETERMINED |
| (a) | | AMOUNT | | AMOUNT |
| COMPONENT | γ- | 70 | PG¹⁾ | 50 |
| (b) | BUTYROLACTONE | | | |
| COMPONENT | WATER | BALANCE | WATER | BALANCE |
| (c) | | | | |
| COMPONENT | 1-THIOGLYCEROL | 0.05 | 1-THIOGLYCEROL | 0.05 |
| (d) | 3-MERCAPTO- | 0.09 | | |
| | PROPIONIC ACID | | | |
| ANOTHER | ACETYLENOL | 0.1 | ACETYLENOL | 0.1 |
| COMPONENT | | | | |

| | PREPARATION | | PREPARATION | |
|---|---|---|---|---|
| COMPOSITION | EXAMPLE 11 | | EXAMPLE 12 | |
| OF STRIPPING | STRIPPING | | STRIPPING | |
| SOLUTION | SOLUTION 11 | wt % | SOLUTION 12 | wt % |
| COMPONENT | NH₄F | 0.05 | NH₄F | 0.15 |
| (a) | | | | |
| COMPONENT | γ- | 95 | γ- | 85 |
| (b) | BUTYROLACTONE | | BUTYROLACTONE | |
| COMPONENT | WATER | BALANCE | WATER | BALANCE |
| (c) | | | | |
| COMPONENT | 1-THIOGLYCEROL | 0.05 | 1-THIOGLYCEROL | 0.05 |
| (d) | | | | |
| ANOTHER | ACETYLENOL | 0.1 | ACETYLENOL | 0.1 |
| COMPONENT | | | | |

¹⁾PG: PROPYLENE GLYCOL

TABLE 2
EXAMINATION OF DAMAGE TO, AND STRIPPABILITY OF LOW-K MATERIAL

| | TEST STRIPPING | ETCHING LEVEL (Å) | STRIPPING |
|---|---|---|---|
| | SOLUTION | OF BPSG FILM | PROPERTIES |
| EXAMPLES 1, 11 | STRIPPING SOLUTION 1 | 6 | ◯ |
| EXAMPLES 2, 12 | STRIPPING SOLUTION 2 | 10 | ◯ |
| EXAMPLES 3, 13 | STRIPPING SOLUTION 3 | 23 | ◯ |
| EXAMPLES 4, 14 | STRIPPING SOLUTION 4 | 53 | ◯ |
| EXAMPLES 5, 15 | STRIPPING SOLUTION 5 | 112 | ◯ |
| EXAMPLES 6, 16 | STRIPPING SOLUTION 6 | 5 | ◯ |
| EXAMPLES 7, 17 | STRIPPING SOLUTION 7 | 6 | ◯ |
| EXAMPLES 8, 18 | STRIPPING SOLUTION 8 | 21 | ◯ |
| EXAMPLES 9, 19 | STRIPPING SOLUTION 9 | 36 | ◯ |
| EXAMPLES 10, 20 | STRIPPING SOLUTION 10 | 60 | ◯ |
| COMPARATIVE EXAMPLE 1, 3 | STRIPPING SOLUTION 11 | 642 | ◯ |
| COMPARATIVE EXAMPLE 2, 4 | STRIPPING SOLUTION 12 | 1575 | ◯ |

As shown in FIG. 1 and in BPSG etching level (angstrom, Å) in Table 2, the stripping solutions 1 to 10 as the photoresist stripping solutions of the present invention were excellent in prevention of damages to BPSG films, and simultaneously exhibited excellent stripping properties as shown in Table 2 (Examples 1 to 10). Particularly, the photoresist stripping solution was excellent when the amount of ammonium fluoride (NH₄F) incorporated as the component (a) was equal to or less than 0.06 mass % based on the total mass of the stripping solution. On the other hand, when the stripping solutions 11 and 12 were used, they showed good results with respect to stripping properties but indicated 642 angstroms (Å) and 1,575 angstroms (Å) in film thickness, respectively as the etching level of the BPSG film, showing that the stripping solutions were poor in damage prevention (Comparative Examples 1 and 2). This damage prevention test using the BPSG film is a technique for easily conducting a damage prevention test on low-k film.

The photoresist stripping solution according to the present invention includes a salt of hydrochloric acid with a base free from metallic ions in a content of 0.001 to 0.1 mass % based on the total mass of the stripping solution, thereby generating no corrosion of metallic wiring including Cu wiring, being excellent in strippability of a photoresist film and residues after ashing, being usable for a low-k film, particularly a low-k film made significantly porous, in a Cu/low-k substrate, and being capable of reducing damages thereto.

Although the present invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A photoresist stripping solution comprising:
(a) a salt of hydrofluoric acid with a base free from metallic ions, and
(b) a water-soluble organic solvent,
wherein the content of the component (a) is 0.001 to 0.1 mass % based on the total mass of the stripping solution.

2. The photoresist stripping solution according to claim 1, wherein the content of the component (a) is 0.001 to 0.06 mass % based on the total mass of the stripping solution.

3. The photoresist stripping solution according to claim 1, wherein the water-soluble organic solvent is at least one member selected from the group consisting of γ-butyro-lactone and propylene glycol.

4. The photoresist stripping solution according to claim 1, which further comprises (c) water and (d) a corrosion preventive.

5. The photoresist stripping solution according to claim 4, wherein the corrosion preventive is at least one member selected from the group consisting of a mercapto group-containing compound and a benzotriazole compound.

6. The photoresist stripping solution according to claim 5, wherein the mercapto group-containing compound is a compound having at least one of a hydroxyl group and a carboxyl group at at least one of the α-position and β-position relative to a mercapto group-bound carbon atom.

7. The photoresist stripping solution according to claim 5, wherein the mercapto group-containing compound is at least one member selected from the group consisting of 1-thioglycerol, 2-mercaptoethanol, 3-(2-aminophenylthio)-2-hydroxypropyl mercaptan, 3-(2-hydroxyethylthio)-2-hydroxy-propyl mercaptan, 2-mercaptopropionic acid, and 3-mercaptopropionic acid.

8. The photoresist stripping solution according to claim 5, wherein the benzotriazole compound is at least one member selected from the group consisting of 1-(2,3-dihydroxypropyl)benzotriazole, 2,2′-{[(4-methyl-1H-benzotriazol-1-yl)methyl]imino}bisethanol, and 2,2′-{[(5-methyl-1H-benzotriazol-1-yl)methyl]imino}bisethanol.

9. The photoresist stripping solution according to claim 4, wherein the content of the component (b) is 20 to 90 mass %, the content of the component (c) is 10 to 80 mass %, and the content of the component (d) is 0.01 to 10 mass % based on the total mass of the photoresist stripping solution.

10. The photoresist stripping solution according to claim 1, wherein the component (a) is ammonium fluoride.

11. The photoresist stripping solution according to claim 10, which further comprises (e) a salt of hydrofluoric acid with at least one of a quaternary ammonium hydroxide and an alkanolamine, the quaternary ammonium hydroxide being represented by formula (1): 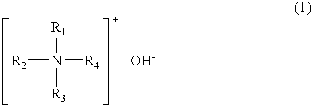
wherein R¹, R², R³, and R⁴ independently represent a C₁ to C₄ alkyl group or a C₁ to C₄ hydroxyalkyl group.

12. The photoresist stripping solution according to claim 11, wherein the mass ratio of the component (a) to the component (e) incorporated is 2:8 to 8:2.

13. The photoresist stripping solution according to claim 1, which is used in a washing treatment of a substrate containing a low-k film consisting of a low-k material having a dielectric constant equal to or less than 2.7.

14. A method of treating a substrate, which comprises:
forming a photoresist film on a substrate;
subjecting it to light exposure and then to development;
etching thereof with a photoresist pattern as a mask pattern;
ashing the mask; and
bringing the photoresist stripping solution of claim 1 into contact with the substrate.
